(19) United States
(12) Patent Application Publication
(10) Pub. No.: US 2026/0143958 A1
(43) Pub. Date: May 21, 2026

(54) METHOD FOR PREPARING PEROVSKITE THIN FILM AND PEROVSKITE CELL

(71) Applicant: SHENZHEN HIKING PV TECHNOLOGY CO., LTD., Shenzhen (CN)

(72) Inventors: Yi DONG, Shenzhen (CN); Haimang YI, Shenzhen (CN); Xiaowei SHEN, Shenzhen (CN); Cheng XU, Shenzhen (CN); Chuan ZHANG, Shenzhen (CN)

(21) Appl. No.: 19/451,259

(22) Filed: Jan. 16, 2026

Related U.S. Application Data
(63) Continuation of application No. PCT/CN2025/104797, filed on Jun. 27, 2025.

(30) Foreign Application Priority Data
Oct. 28, 2024 (CN) 202411509609.1

(51) Int. Cl. H10K 71/00; H10K 30/40

(52) U.S. Cl. CPC H10K 71/311; H10K 30/40

(57) ABSTRACT

The present application provides a method for preparing a perovskite thin film and a perovskite cell. The perovskite cell includes a cell baseplate, a first electrode layer, a first carrier transport layer, a carrier transport passivation layer, a perovskite thin film, a second carrier transport layer, and a second electrode layer. In the present application, by adding a thickener into a perovskite inorganic salt solution, fluid characteristics of the perovskite inorganic salt solution can be effectively improved, resulting in a high-viscosity first inorganic substrate layer. The fluidity of the first inorganic substrate layer decreases as the temperature decreases, thereby enabling stable deposition and adhesion of the first inorganic substrate layer on a cell substrate.

### CROSS-REFERENCE TO RELATED APPLICATIONS

The present application is a continuation of International Application No. PCT/CN2025/104797, filed on Jun. 27, 2025, which claims priority to Chinese Patent Application No. 202411509609.1, filed on Oct. 28, 2024, the entire disclosure of which is incorporated herein by reference.

### FIELD OF TECHNOLOGY

The present application belongs to the technical field of batteries, and more particularly relates to a method for preparing a perovskite thin film and a perovskite cell prepared by using the method for preparing a perovskite thin film.

### BACKGROUND

In the field of perovskite cells, wet processes for preparing perovskite thin films mainly include a one-step method and a two-step method. The one-step method includes blending perovskite precursor materials in a solvent to formulate a perovskite precursor solution, and coating the perovskite precursor solution onto a substrate; subsequently, rapidly removing the solvent by a process such as anti-solvent extraction or vacuuming to achieve rapid supersaturation of a wet film and thus pre-crystallization; and finally, subjecting the pre-crystallized film to annealing to obtain a perovskite thin film. Due to many crystal defects, the one-step method results in a perovskite cell with relatively lower photoelectric conversion efficiency. The two-step method includes first formulating a perovskite inorganic salt solution, and coating the same onto a substrate for annealing to form an inorganic substrate layer; and subsequently, infiltrating an organic halide salt solution into the inorganic substrate layer and annealing to form a perovskite thin film. The perovskite thin film prepared by the two-step method has higher crystallinity and compactness, and a perovskite cell prepared therefrom usually has higher photoelectric conversion efficiency.

In the current two-step method, the inorganic substrate layer is usually formed by coating the perovskite inorganic salt solution onto the substrate using a slot die coating or blade coating method, followed by annealing. However, the inorganic substrate layer prepared above has defects such as poor uniformity and a large number of holes, resulting in serious defects in the perovskite thin film formed by combining the organic halide salt solution with the inorganic substrate layer, which affects the photoelectric conversion efficiency and long-term stability of the perovskite cell.

### SUMMARY

An objective of embodiments of the present application is to provide a method for preparing a perovskite thin film and a perovskite cell, so as to solve the problems in the related art that an inorganic substrate layer has defects such as poor uniformity and a large number of holes, results in serious defects in a perovskite thin film formed by combining an organic halide salt solution with the inorganic substrate layer, and affects the photoelectric conversion efficiency and long-term stability of a perovskite cell.

To achieve the above objective, technical solutions adopted in the embodiments of the present application are as follows.

In one aspect, a method for preparing a perovskite thin film is provided, which includes the following steps:
coating a perovskite inorganic salt solution containing a thickener onto a cell substrate, performing annealing treatment to form a first inorganic substrate layer, and combining the cell substrate with the first inorganic substrate layer to form a wet film substrate;
cooling and standing the wet film substrate, and removing an organic solvent in the first inorganic substrate layer by a vacuum flash evaporation manner to form a pre-dried film layer, where the pre-dried film layer consists of a perovskite inorganic salt material and the thickener;
performing first annealing treatment on the pre-dried film layer to remove cations in the thickener;
performing second annealing treatment on the pre-dried film layer to remove anions in the thickener and obtain a second inorganic substrate layer; and
coating an organic halide salt solution onto the second inorganic substrate layer, and performing drying and annealing treatment to obtain the perovskite thin film.

In one embodiment, the perovskite inorganic salt solution is formed by mixing the perovskite inorganic salt material and a solvent; the perovskite inorganic salt material is AX and BX₂, where A is a monovalent metal cation including one or more of cesium and rubidium; B is a divalent metal cation including one or more of lead and tin; X is a monovalent anion including one or more of iodine, bromine, and chlorine; and the solvent includes one or more of dimethyl sulfoxide, N,N-dimethylformamide, and N-methylpyrrolidone.

In one embodiment, the thickener includes one of ionic surfactants such as methylammonium acetate, methylammonium formate, and methylammonium propionate.

In one embodiment, a manner for coating the perovskite inorganic salt solution includes one of deposition processes such as slot die coating, blade coating, screen printing, and spray coating.

In one embodiment, in the step of cooling and standing the wet film substrate, and removing an organic solvent in the first inorganic substrate layer by a vacuum flash evaporation manner to form a pre-dried film layer, where the pre-dried film layer consists of a perovskite inorganic salt material and the thickener: a cooling rate is in a range of 1-30° C./min, a cooling and standing temperature is in a range of −5-20° C., and a standing duration is in a range of 0-400 min.

In one embodiment, in the step of performing first annealing treatment on the pre-dried film layer to remove cations in the thickener: an annealing temperature is in a range of 40-90° C., and an annealing duration is in a range of 1-800 min.

In one embodiment, in the step of performing second annealing treatment on the pre-dried film layer to remove anions in the thickener and obtain a second inorganic substrate layer: an annealing temperature is in a range of 120-200° C., and an annealing duration is in a range of 1-500 min.

In one embodiment, the organic halide salt solution is formed by mixing a solute and a solvent; the solvent of the organic halide salt solution includes one of isopropanol, ethanol, and n-butanol, etc.; the solute of the organic halide salt solution is CX, where C is a monovalent organic cation including one or more of methylamino, formamidino, and a phenylethylammonium halide salt; and X is a monovalent anion including one or more of iodine, bromine, and chlorine.

In one embodiment, in the step of coating an organic halide salt solution onto the second inorganic substrate layer, and performing drying and annealing treatment to obtain the perovskite thin film: after the organic halide salt solution is coated onto the second inorganic substrate layer, standing is performed to wait for 1-5,000 s, and then the drying and the annealing treatment are performed.

In another aspect, a perovskite cell is provided, which includes:
a cell baseplate;
a first electrode layer disposed on the cell baseplate;
a first carrier transport layer disposed on the first electrode layer;
a carrier transport passivation layer disposed on the first carrier transport layer;
a perovskite thin film disposed on the carrier transport passivation layer;
a second carrier transport layer disposed on the perovskite thin film; and
a second electrode layer disposed on the second carrier transport layer;
where the perovskite thin film is prepared by the method for preparing a perovskite thin film as provided in any one of the above embodiments.

The method for preparing a perovskite thin film and the perovskite cell provided by the embodiments of the present application at least have the following beneficial effects. In the present application, by adding the thickener into the perovskite inorganic salt solution, fluid characteristics of the perovskite inorganic salt solution can be effectively improved, resulting in the high-viscosity first inorganic substrate layer. The fluidity of the first inorganic substrate layer decreases as the temperature decreases, thereby enabling stable deposition and adhesion of the first inorganic substrate layer on the cell substrate. By cooling and standing the wet film substrate and using a vacuum flash evaporation process, the wet film can be uniformly and preliminarily cured, thereby decreasing the fluidity of the wet film. The perovskite thin film prepared by subjecting the wet film to annealing treatment twice and then combining with the organic halide salt solution has high quality, which is conducive to improving the photoelectric conversion efficiency and long-term stability of the perovskite cell.

### BRIEF DESCRIPTION OF THE DRAWINGS

To more clearly illustrate the technical solutions in the embodiments of the present application, a brief introduction to the drawings required to be used in the embodiments or exemplary technical descriptions is given below. It is obvious that the drawings described below are only some embodiments of the present application, and for those of ordinary skill in the art, other drawings can also be obtained according to these drawings without exerting creative labor.

FIG. 1 is a flow diagram of a method for preparing a perovskite thin film provided by an embodiment of the present application; and

FIG. 2 is a structural schematic diagram of a perovskite cell provided by an embodiment of the present application.

### DESCRIPTION OF THE EMBODIMENTS

To make the technical problems to be solved, technical solutions, and beneficial effects of the present application clearer, the present application is further described in detail below in conjunction with the drawings and embodiments. It should be understood that the specific embodiments described herein are only for explaining the present application and are not intended to limit the present application.

It should be noted that when an element is described as being “fixed to” or “disposed on” another element, it may be directly on the other element or indirectly on the other element. When an element is described as being “connected to” another element, it may be directly connected to the other element or indirectly connected to the other element.

Furthermore, the terms “first” and “second” are used only for descriptive purposes and should not be understood as indicating or implying relative importance or implicitly indicating a quantity of indicated technical features. Thus, features defined as “first” or “second” may explicitly or implicitly include one or more of such features. In the description of the present application, the term “multiple” means two or more, unless otherwise explicitly and specifically defined. The term “several” means one or more, unless otherwise explicitly and specifically defined.

In the description of the present application, it should be understood that the terms “center”, “length”, “width”, “thickness”, “upper”, “lower”, “front”, “rear”, “left”, “right”, “vertical”, “horizontal”, “top”, “bottom”, “inner”, “outer”, and the like indicate orientation or position relationships based on orientation or position relationships shown in the drawings, which are only for the convenience of describing the present application and simplifying the description, rather than to indicate or imply that a device or element referred to needs to have a particular orientation or be constructed and operated in a particular orientation, and therefore should not be construed as limiting the present application.

In the description of the present application, it should be noted that unless otherwise explicitly specified and defined, the terms “mount”, “connect”, and “connection” should be understood in a broad sense. For example, the terms may refer to fixed connection, detachable connection, or integrated connection; may refer to mechanical connection or electrical connection; may refer to direct connection or indirect connection through an intermediate medium; and may refer to internal communication of two elements or an interaction relationship between two elements. For those of ordinary skill in the art, specific meanings of the above terms in the present application may be understood according to specific cases.

Reference to “one embodiment” or “an embodiment” throughout the specification means that a particular feature, structure, or characteristic described in conjunction with the embodiment is included in at least one embodiment of the present application. Therefore, the phrase “in one embodiment” or “in some embodiments” appearing in various places throughout the specification does not necessarily refer to the same embodiment. Furthermore, in one or more embodiments, specific features, structures, or characteristics may be combined in any suitable manner.

Currently, in the process of preparing an inorganic substrate layer for a perovskite thin film prepared by a two-step method, a perovskite inorganic salt solution is coated onto a substrate by a slot die coating or blade coating method and then annealed to form the inorganic substrate layer. Due to the mismatch between fluid characteristics of a solvent in the perovskite inorganic salt solution and a coating process, the inorganic substrate layer prepared by the large-area coating process has poor quality, which has defects such as poor uniformity and a large number of holes, results in serious defects in the perovskite thin film formed by a reaction with an organic halide salt solution, and affects the photoelectric conversion efficiency and long-term stability of a perovskite cell.

To solve the above problems, the embodiments of the present application provide a method for preparing a perovskite thin film and a perovskite cell. For the convenience of description, a specific structure of the perovskite cell is described in detail below.

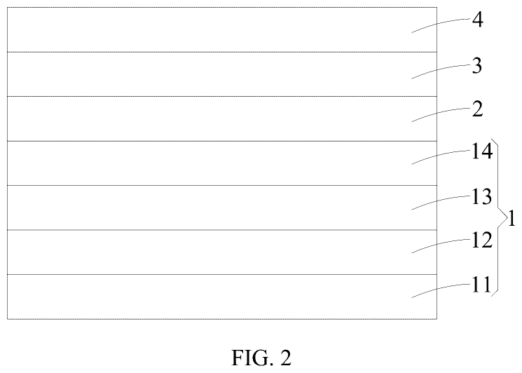

Referring to FIG. 2, the specific structure of the perovskite cell from bottom to top includes a cell baseplate 11, a first electrode layer 12 disposed on a cell substrate, a first carrier transport layer 13 disposed on the first electrode layer 12, a carrier transport passivation layer 14 disposed on the first carrier transport layer 13, a perovskite thin film 2 disposed on the carrier transport passivation layer 14, a second carrier transport layer 3 disposed on the perovskite thin film 2, and a second electrode layer 4 disposed on the second carrier transport layer 3. In conjunction with the specific structure of the perovskite cell, a preparation direction of the perovskite cell is described in detail below. A method for preparing the perovskite cell specifically includes steps as follows.

Step 1: The cell baseplate 11 is provided. The cell baseplate 11 may be a transparent glass baseplate.

Step 2: The first electrode layer 12 is prepared on the cell baseplate 11.

Step 3: The first carrier transport layer 13 is prepared on the first electrode layer 12. Optionally, the first carrier transport layer 13 includes, but is not limited to, one or more of NiO, SnO₂, TiO₂, and 2PACz, and is deposited by process methods such as magnetron sputtering, evaporation, spray coating, and slot die coating. Specifically, in the embodiments of the present application, NiO may be selected as a material for the first carrier transport layer 13, the magnetron sputtering is adopted as a deposition method, and the first carrier transport layer 13 prepared has a film thickness of 50 nm.

Step 4: The carrier transport passivation layer 14 is prepared on the first carrier transport layer 13.

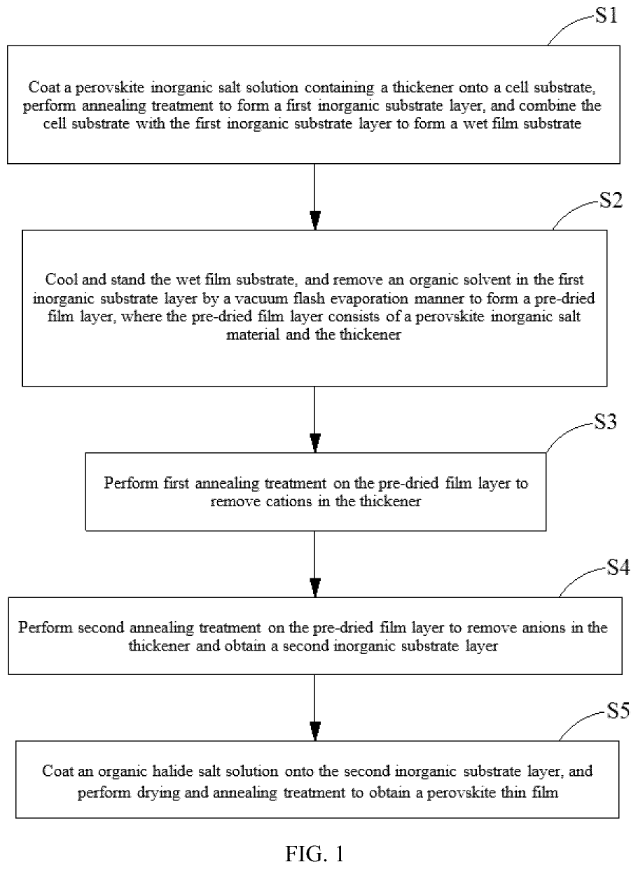

Step 5: The perovskite thin film 2 is prepared on the carrier transport passivation layer 14. Here, the perovskite thin film 2 is prepared by the method for preparing a perovskite thin film provided in the embodiments of the present application. Referring to FIG. 1, the method for preparing a perovskite thin film provided in the embodiments of the present application specifically includes steps as follows.

S1. A perovskite inorganic salt solution containing a thickener is coated onto a cell substrate 1 and subjected to annealing treatment to form a first inorganic substrate layer, and the cell substrate 1 is combined with the first inorganic substrate layer to form a wet film substrate. The cell substrate 1 may be a sheet prepared and formed in the above steps 1 to 4, and its specific structure includes the cell baseplate 11, the first electrode layer 12, the first carrier transport layer 13, and the carrier transport passivation layer 14.

The perovskite inorganic salt solution may be formed by mixing a perovskite inorganic salt material and a solvent. The perovskite inorganic salt material may be AX and BX₂, where A is a monovalent metal cation, including but not limited to one or more of cesium and rubidium. B is a divalent metal cation, including but not limited to one or more of lead and tin. X is a monovalent anion, including but not limited to one or more of iodide, bromide, chloride, or pseudo-halogen. The solvent includes, but is not limited to, one or more of dimethyl sulfoxide, N,N-dimethylformamide, and N-methylpyrrolidone.

The thickener includes, but is not limited to, one or more of ionic surfactants such as methylammonium acetate (MAAC), methylammonium formate (MAFA), and methylammonium propionate (MAPA).

A manner for coating the perovskite inorganic salt solution includes, but is not limited to, deposition processes such as slot die coating, blade coating, screen printing, and spray coating.

Specifically, in the embodiments of the present application, the perovskite inorganic salt material may be obtained by mixing PbI₂, PbBr₂, CsI, and FAI in a certain ratio. The solvent in the perovskite inorganic salt solution may be dimethyl sulfoxide (DMSO). The thickener may be methylammonium acetate (MAAC). The perovskite inorganic salt solution is formulated at 1 mol/L according to a volume ratio of DMSO to MAAC being 1:50. The above perovskite inorganic salt solution is printed onto the cell substrate 1 by screen printing and then subjected to annealing treatment to form the first inorganic substrate layer. A printing mesh plate adopted may be a 240-420 mesh polyester wire mesh or stainless steel wire mesh with a tension range of 10-24 N. An annealing temperature is in a range of 40-300° C., and an annealing time is in a range of 3-400 min. In the embodiments of the present application, a 300-mesh polyester wire mesh is adopted for performing the coating operation of the perovskite inorganic salt solution.

S2. The wet film substrate is cooled and allowed to stand, and an organic solvent in the first inorganic substrate layer is removed by a vacuum flash evaporation manner to form a pre-dried film layer, where the pre-dried film layer consists of the perovskite inorganic salt material and the thickener. The organic solvent in the first inorganic substrate layer may be the solvent in the above perovskite inorganic salt solution. Optionally, a cooling rate is in a range of 1-30° C./min, a cooling and standing temperature is in a range of −5-20° C., and a standing duration is in a range of 0-400 min. An air pressure in a vacuum chamber needs to drop to 1.0×10⁻²-1.0×10⁻⁵ kPa within 1-1.5 s. Specifically, in the embodiments of the present application, the cooling rate may be 5° C./min, the cooling and standing temperature may be 5° C., and the standing duration may be 5 min. The air pressure in the vacuum chamber drops to 3.5×10⁻² kPa within 5 s. With this structure, due to the presence of the thickener, the fluidity of the first inorganic substrate layer decreases as the temperature decreases, thereby enabling stable deposition and adhesion of the first inorganic substrate layer on the cell substrate 1.

S3. The pre-dried film layer is subjected to first annealing treatment to remove cations in the thickener. It is to be understood that after the completion of vacuuming, the first inorganic substrate layer is subjected to the first annealing treatment, thereby removing anions, such as Ac·, PA·, and FA·, in the thickener, and leaving cations in the thickener and the perovskite inorganic salt material. Optionally, an annealing temperature is in a range of 40-90° C., and an annealing duration is in a range of 1-800 min. Specifically, in the embodiments of the present application, the annealing temperature may be 60° C., and the annealing duration may be 200 min.

S4. The pre-dried film layer is subjected to second annealing treatment to remove anions in the thickener and obtain a second inorganic substrate layer. The second annealing treatment can completely heat and decompose the thickener, that is, can remove the anions in the thickener and leave the perovskite inorganic salt material. In this way, a uniform and high-purity perovskite inorganic substrate layer can be formed. Optionally, an annealing temperature is in a range of 120-200° C., and an annealing duration is in a range of 1-500 min. Specifically, in the embodiments of the present application, the annealing temperature may be 140° C., and the annealing duration may be 60 min.

S5. An organic halide salt solution is coated onto the second inorganic substrate layer and then subjected to drying and annealing treatment to obtain the perovskite thin film 2. First, the organic halide salt solution is formulated. Optionally, the organic halide salt solution is formed by mixing a solute and a solvent. The solvent of the organic halide salt solution includes, but is not limited to, volatile solvents such as isopropanol, ethanol, and n-butanol, which do not dissolve the second inorganic substrate layer. The solute of the organic halide salt solution may be CX, where C is a monovalent organic cation, including but not limited to one or more cations of methylamino, formamidino, and a phenylethylammonium halide salt; and X is a monovalent anion, including but not limited to one or more anions of iodide, bromide, chloride, or pseudo-halogen. Specifically, in the embodiments of the present application, the solvent of the organic halide salt solution may be n-butanol, the solute of the organic halide salt solution may be obtained by mixing FAI, MAI, and FABr in a certain ratio, and the organic halide salt solution is formulated at 15 mg/mL.

Second, the organic halide salt solution is coated onto the second inorganic substrate layer to form an organic halide salt solution liquid film, and after a full reaction with the second inorganic substrate layer, the organic halide salt solution liquid film is pre-crystallized and dried by a drying process to form a perovskite pre-crystallized thin film nucleus. Optionally, a manner for coating the organic halide salt solution onto the second inorganic substrate layer includes, but is not limited to, processes such as slot die coating, blade coating, screen printing, and spray coating. After the organic halide salt solution is coated onto the second inorganic substrate layer, a reaction time of 1-5,000 s is required for waiting. A drying process includes, but is not limited to, processes such as natural drying, blow drying, and infrared drying; and a drying duration is in a range of 1-5,000 s. Specifically, in the embodiments of the present application, the organic halide salt solution is coated onto the second inorganic substrate layer by a slot die coating process, allowed to wait for 20 s, and then blown with a fan at 5 mm/s.

Finally, the perovskite pre-crystallized thin film is subjected to annealing treatment to obtain the perovskite thin film 2. Optionally, an annealing temperature is in a range of 70-300° C., and an annealing time is in a range of 1-600 min. Specifically, in the embodiments of the present application, the annealing temperature may be 140° C., and the annealing time may be 300 min.

Step 6: The second carrier transport layer 3 is prepared on the perovskite thin film 2. Optionally, the second carrier transport layer 3 may be made of C₆₀ and SnO₂ materials. Specifically, C₆₀ and SnO₂ film layers are sequentially deposited on the perovskite thin film 2 by an evaporation manner. A thickness of the C₆₀ film layer may be 34 nm, and a thickness of the SnO₂ film layer may be 20 nm.

Step 7: The second electrode layer 4 is prepared on the second carrier transport layer 3. Optionally, the second electrode layer 4 may be made of a copper material. Specifically, the copper material is deposited on the second carrier transport layer 3 by an evaporation manner, and a thickness of the second electrode layer 4 may be 150 nm.

To verify the performance of the perovskite cell prepared by the method for preparing a perovskite thin film provided in the embodiments of the present application, the embodiments of the present application provide four sets of tests for comparative demonstration, namely Example 1, Comparative Example 1, Comparative Example 2, and Comparative Example 3.

According to a method for preparing a perovskite cell provided in Example 1, the perovskite cell is prepared by the above steps 1 to 7.

The difference between a method for preparing a perovskite cell provided in Comparative Example 1 and the method for preparing a perovskite cell provided in Example 1 lies in a difference in a method for preparing the perovskite thin film in step 5. In Comparative Example 1, the perovskite thin film 2 is prepared by a one-step method, which specifically includes steps as follows.

Step 1: With N,N-dimethylformamide (DMF)/DMSO as a solvent and CsI, PbI₂, PbBr₂, and FAI as perovskite precursor materials, the perovskite precursor materials are blended in the solvent to formulate a perovskite precursor solution.

Step 2: A perovskite wet film is prepared on the cell substrate 1 by a blade coating manner, and a solvent in the perovskite wet film is rapidly removed by a vacuum flash evaporation manner to form a pre-crystallized dry film.

Step 3: The pre-crystallized dry film is subjected to annealing treatment to form the perovskite thin film 2.

Other steps of the method for preparing a perovskite cell provided in Comparative Example 1 are the same as the corresponding steps of the method for preparing a perovskite cell provided in Example 1, which are not repeatedly described herein.

The difference between a method for preparing a perovskite cell provided in Comparative Example 2 and the method for preparing a perovskite cell provided in Example 1 lies in a difference in a method for preparing the perovskite thin film in step 5. In Comparative Example 2, specific steps for preparing the perovskite thin film 2 are as follows.

Step 1: With DMF/N-methylpyrrolidone (NMP) as a solvent and CsI, PbI₂, PbBr₂, and FAI as perovskite precursor materials, the perovskite precursor materials are blended in the solvent to formulate a perovskite inorganic salt solution.

Step 2: The perovskite inorganic salt solution is coated onto the cell substrate 1 by a blade coating manner and then annealed to form an inorganic substrate layer.

Other steps of the method for preparing a perovskite cell provided in Comparative Example 2 are the same as the corresponding steps of the method for preparing a perovskite cell provided in Example 1, which are not repeatedly described herein.

The difference between a method for preparing a perovskite cell provided in Comparative Example 3 and the method for preparing a perovskite cell provided in Example 1 lies in a difference in a method for preparing the perovskite thin film in step 5. In Comparative Example 3, specific steps for preparing the perovskite thin film 2 are as follows.

Step 1: With CsI, PbI₂, PbBr₂, and FAI as perovskite inorganic salt materials, DMSO as a solvent for a perovskite inorganic salt solution, and MAAC as a thickener, the perovskite inorganic salt solution is formulated at 1 mol/L according to a volume ratio of DMSO to MAAC being 1:50.

Step 2: The perovskite inorganic salt solution is printed onto the cell substrate 1 by screen printing. A printing mesh plate adopted may be a 240-420 mesh polyester wire mesh or stainless steel wire mesh with a tension range of 10-24 N. Specifically, in Comparative Example 3, a 300-mesh polyester wire mesh is adopted for performing the coating operation of the perovskite inorganic salt solution.

Step 3: After the completion of printing, a wet film of the perovskite inorganic salt solution is subjected to annealing treatment to form an inorganic substrate layer. An annealing temperature is in a range of 40-300° C., and an annealing time is in a range of 3-400 min. Specifically, in Comparative Example 3, the annealing temperature adopted is 150° C., and the annealing time is 30 min.

Other steps of the method for preparing a perovskite cell provided in Comparative Example 3 are the same as the corresponding steps of the method for preparing a perovskite cell provided in Example 1, which are not repeatedly described herein.

Viscosity characteristics of the perovskite inorganic salt solution in Example 1, viscosity characteristics of the perovskite precursor solution in Comparative Example 1, and viscosity characteristics of the perovskite inorganic salt solution in Comparative Example 2 were respectively tested at 20-40° C. using a rheometer. Test results are shown in the table below.

| | Viscosity (mPa · s) | | | | |
|---|---|---|---|---|---|
| Solution | 20° C. | 25° C. | 30° C. | 35° C. | 40° C. |
| Example 1 | 3651.25 | 3254.45 | 2841.57 | 2420.54 | 1965.45 |
| Comparative | 6.99 | 6.29 | 5.66 | 4.89 | 4.28 |
| Example 1 | | | | | |
| Comparative | 1.20 | 1.11 | 0.92 | 0.82 | 0.65 |
| Example 2 | | | | | |

From the comparison of the above data, it can be seen that the viscosity of the perovskite inorganic salt solution provided in Example 1 is obviously higher than that of the perovskite precursor solution provided in Comparative Example 1 and the perovskite inorganic salt solution provided in Comparative Example 2. It can be concluded that due to the addition of the thickener, the viscosity of the perovskite inorganic salt solution provided in Example 1 is obviously increased. When the volume ratio of DMSO to MAAC is 1:50, fluidity requirements of the screen printing process can be met.

A solar simulator was used to perform a standard solar intensity calibration, and a long-term IV test was carried out on a perovskite cell with an area of 1.0 cm², with an initial voltage set at 0 V, a cutoff voltage at 1.3 V, and a range at 100 mA. Test results are shown in the table below.

| | | | | Photovoltaic |
|---|---|---|---|---|
| | Short-circuit | Open-circuit | Fill | conversion |
| | current density | voltage | factor | efficiency |
| Device | Jsc (mA/cm²) | Voc (mV) | FF (%) | PCE (%) |
| Example 1 | 20.88 | 1.21 | 82.4 | 20.81 |
| Comparative | 18.55 | 1.02 | 75.5 | 15.09 |
| Example 1 | | | | |
| Comparative | 19.52 | 1.18 | 77.5 | 17.91 |
| Example 2 | | | | |
| Comparative | 18.22 | 1.02 | 70.5 | 13.10 |
| Example 3 | | | | |

From the comparison of the above data, the following can be seen.

1. From the comparison of Example 1 and Comparative Example 1, it can be seen that the performance of the perovskite cell obtained by using the one-step method to prepare the perovskite thin film 2 is obviously lower than that of the perovskite cell obtained by using the two-step method to prepare the perovskite thin film 2.

2. From the comparison of Example 1 and Comparative Example 2, it can be seen that the performance of the perovskite cell obtained by adding the thickener to prepare the perovskite thin film 2 is obviously higher than that of the perovskite cell obtained without using the thickener agent to prepare the perovskite thin film 2.

3. From the comparison of Example 1 and Comparative Example 3, it can be seen that as the step of adding the thickener to prepare the perovskite thin film 2 does not include treatments such as cooling curing and vacuum flash evaporation in Comparative Example 3, the obtained inorganic substrate layer has poor quality, and thus, the prepared perovskite cell has low photovoltaic conversion efficiency.

The above description shows only optional embodiments of the present application and is not intended to limit the present application. Any modifications, equivalent substitutions, and improvements made within the spirit and principles of the present application shall be included within the scope of protection of the present application.

What is claimed is:

1. A method for preparing a perovskite thin film, comprising the following steps:
coating a perovskite inorganic salt solution containing a thickener onto a cell substrate to form a first inorganic substrate layer, and combining the cell substrate with the first inorganic substrate layer to form a wet film substrate, wherein the perovskite inorganic salt solution is formed by mixing a perovskite inorganic salt material and a solvent, the perovskite inorganic salt material is obtained by mixing PbI₂, PbBr₂, CsI, and FAI in a certain ratio, the solvent in the perovskite inorganic salt solution is dimethyl sulfoxide, the thickener is methylammonium acetate, and the perovskite inorganic salt solution is formulated at 1 mol/L according to a volume ratio of the dimethyl sulfoxide to the methylammonium acetate being 1:50;
cooling and standing the wet film substrate, and removing an organic solvent in the first inorganic substrate layer by a vacuum flash evaporation manner to form a pre-dried film layer, wherein the pre-dried film layer consists of the perovskite inorganic salt material and the thickener;
performing first annealing treatment on the pre-dried film layer to remove cations in the thickener;
performing second annealing treatment on the pre-dried film layer to remove anions in the thickener and obtain a second inorganic substrate layer; and
coating an organic halide salt solution onto the second inorganic substrate layer, and performing drying and annealing treatment to obtain the perovskite thin film, wherein the organic halide salt solution is formed by mixing a solute and a solvent; and the solvent of the organic halide salt solution is n-butanol, the solute of the organic halide salt solution is obtained by mixing FAI, MAI, and FABr in a certain ratio, and a concentration of the organic halide salt solution is 15 mg/mL.

2. The method for preparing a perovskite thin film according to claim 1, wherein a manner for coating the perovskite inorganic salt solution comprises one of deposition processes such as slot die coating, blade coating, screen printing, and spray coating.

3. The method for preparing a perovskite thin film according to claim 1, wherein in the step of cooling and standing the wet film substrate, and removing an organic solvent in the first inorganic substrate layer by a vacuum flash evaporation manner to form a pre-dried film layer, wherein the pre-dried film layer consists of the perovskite inorganic salt material and the thickener: a cooling rate is in a range of 1-30° C./min, a cooling and standing temperature is in a range of −5-20° C., and a standing duration is in a range of 0-400 min.

4. The method for preparing a perovskite thin film according to claim 1, wherein in the step of performing first annealing treatment on the pre-dried film layer to remove cations in the thickener: an annealing temperature is in a range of 40-90° C., and an annealing duration is in a range of 1-800 min.

5. The method for preparing a perovskite thin film according to claim 1, wherein in the step of performing second annealing treatment on the pre-dried film layer to remove anions in the thickener and obtain a second inorganic substrate layer: an annealing temperature is in a range of 120-200° C., and an annealing duration is in a range of 1-500 min.

6. The method for preparing a perovskite thin film according to claim 1, wherein in the step of coating an organic halide salt solution onto the second inorganic substrate layer, and performing drying and annealing treatment to obtain the perovskite thin film: after the organic halide salt solution is coated onto the second inorganic substrate layer, standing is performed to wait for 1-5,000 s, and then the drying and the annealing treatment are performed.

7. A perovskite cell, comprising:
a cell baseplate;
a first electrode layer disposed on the cell baseplate;
a first carrier transport layer disposed on the first electrode layer;
a carrier transport passivation layer disposed on the first carrier transport layer;
a perovskite thin film disposed on the carrier transport passivation layer;
a second carrier transport layer disposed on the perovskite thin film; and
a second electrode layer disposed on the second carrier transport layer;
wherein the perovskite thin film is prepared by the method for preparing a perovskite thin film according to claim 1.
